(19) United States
(12) Patent Application Publication
(10) Pub. No.: US 2025/0366059 A1
(43) Pub. Date: Nov. 27, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Chun-Fu LU, Hsinchu (TW); Lung-Kun CHU, New Taipei (TW); Jia-Ni YU, New Taipei (TW); Chung-Wei HSU, Hsinchu (TW); Shih-Hao LAI, Hsinchu (TW); Kuo-Cheng CHIANG, Hsinchu (TW); Chih-Hao WANG, Hsinchu (TW)

(21) Appl. No.: 19/294,338

(22) Filed: Aug. 8, 2025

Related U.S. Application Data
(63) Continuation of application No. 18/421,144, filed on Jan. 24, 2024.
(60) Provisional application No. 63/589,112, filed on Oct. 10, 2023.

(51) Int. Cl. H10D 30/67; H10D 30/01; H10D 30/43; H10D 62/10; H10D 64/01; H10D 84/01; H10D 84/03; H10D 84/83

(52) U.S. Cl. CPC H10D 30/6735; H10D 30/014; H10D 30/43; H10D 30/6757; H10D 62/121; H10D 64/017; H10D 64/021; H10D 84/013; H10D 84/0135; H10D 84/0147; H10D 84/038; H10D 84/83

(57) ABSTRACT

A semiconductor device structure is provided. The structure includes a gate dielectric layer disposed over a substrate, a gate electrode layer disposed over the gate dielectric layer, a plurality of semiconductor layers vertically stacked over the substrate, wherein the gate electrode layer surrounds a portion of each of the semiconductor layers, a first gate spacer disposed adjacent the gate dielectric layer, wherein the first gate spacer comprises an inner surface facing the gate dielectric layer and an outer surface opposite the inner surface, and the first gate spacer includes an oxygen concentration that decreases from the inner surface towards the outer surface, and a dielectric spacer disposed between two adjacent semiconductor layers of the plurality of semiconductor layers, wherein the dielectric spacer comprises an inner surface facing the gate dielectric layer and an outer surface opposite the inner surface, and the dielectric spacer includes an oxygen concentration that decreases from the inner surface towards the outer surface.

### CROSS-REFERENCE TO RELATED APPLICATIONS

This application is a continuation application of U.S. patent application Ser. No. 18/421,144 filed Jan. 24, 2024, which claims priority to U.S. Provisional Application Ser. No. 63/589,112 filed Oct. 10, 2023, which is incorporated by reference in their entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing of ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5 are perspective views of various stages of manufacturing a semiconductor device structure, in accordance with some embodiments.

FIGS. 6-9 are cross-sectional side views of various stages of manufacturing the semiconductor device structure taken along line A-A of FIG. 5, in accordance with some embodiments.

FIG. 10 is a perspective view of the semiconductor device structure of FIG. 9, in accordance with some embodiments.

FIGS. 11-28 are cross-sectional side views of various stages of manufacturing the semiconductor device structure taken along line A-A of FIG. 5, in accordance with some embodiments.

FIGS. 16-1, 16-2, 16-3, 17-1, 17-2, 27-1, and 27-2 are enlarged views of a portion of the semiconductor device structure showing an oxidation profile, in accordance with some embodiments.

FIG. 29 illustrates a portion of the semiconductor device structure of FIG. 28, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

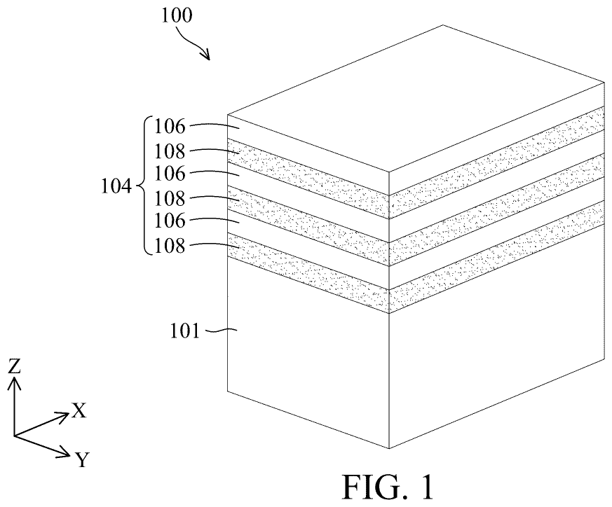

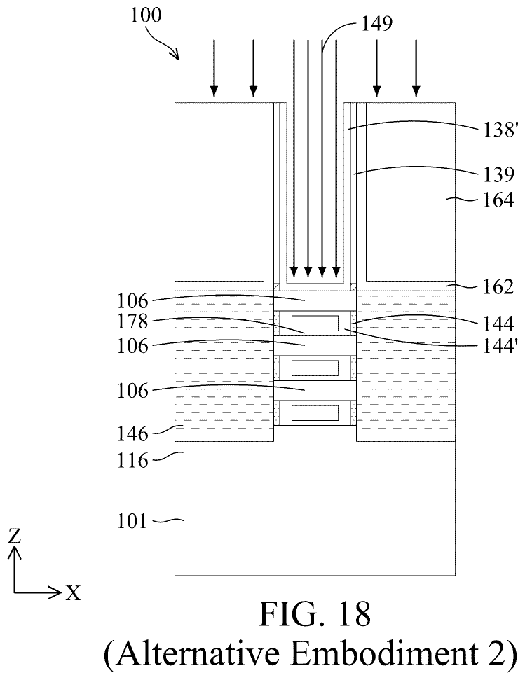

FIGS. 1-29 show exemplary processes for manufacturing a semiconductor device structure 100 according to embodiments of the present disclosure. It is understood that additional operations can be provided before, during, and after processes shown by FIGS. 1-29, and some of the operations described below can be replaced or eliminated, for additional embodiments of the method. The order of the operations/processes is not limiting and may be interchangeable.

FIGS. 1-5 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GalnP, GalnAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

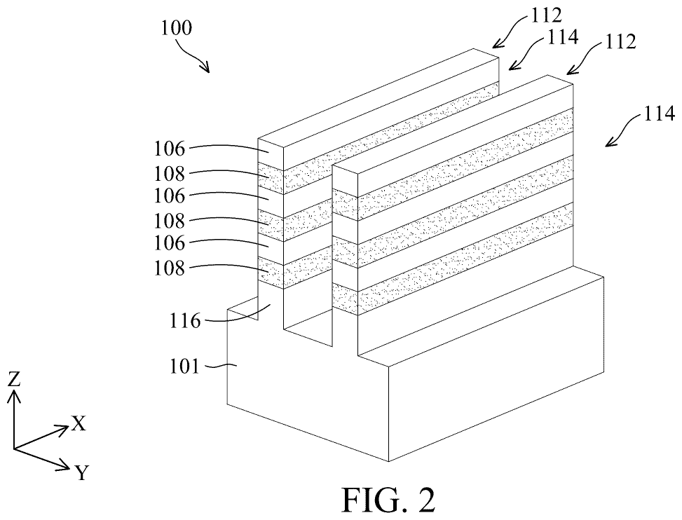

As shown in FIG. 2, fin structures 112 are formed from the stack of semiconductor layers 104. Each fin structure 112 has an upper portion including the semiconductor layers 106, 108 and a well portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

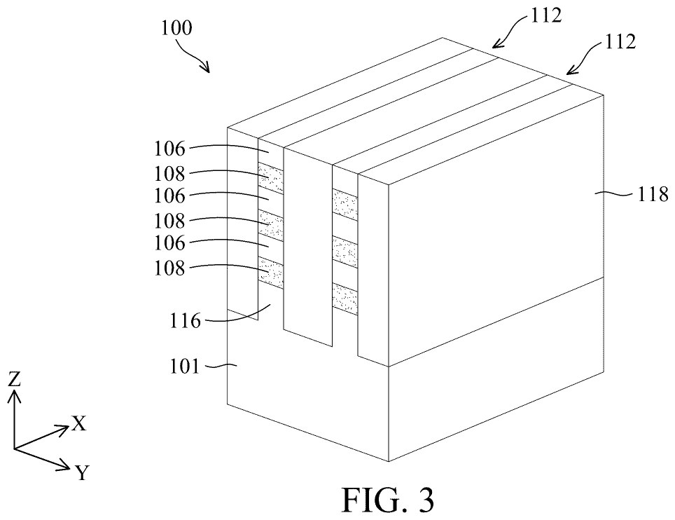

As shown in FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

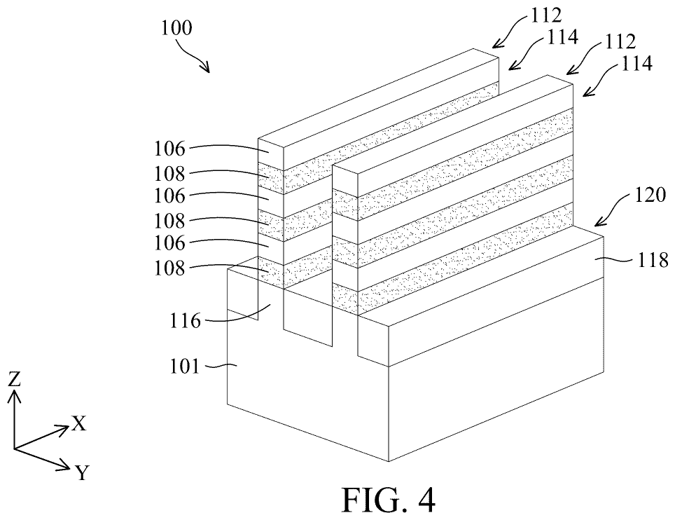

As shown in FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the well portion 116 formed from the substrate 101.

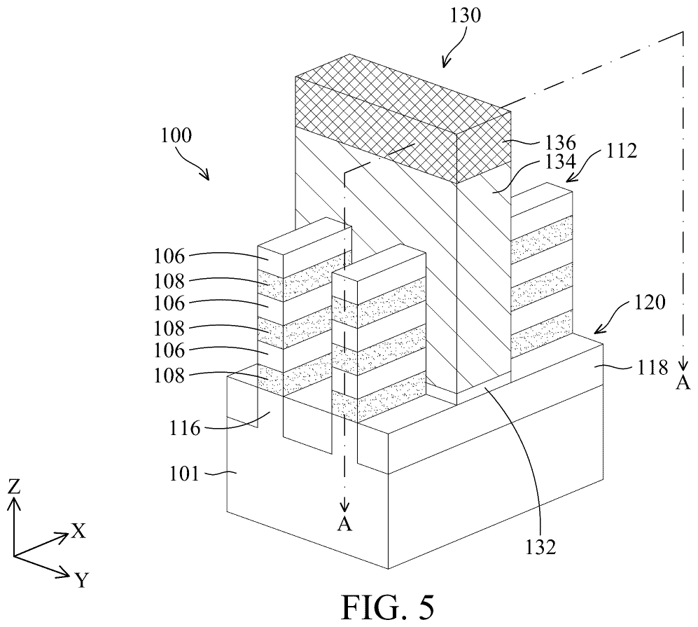

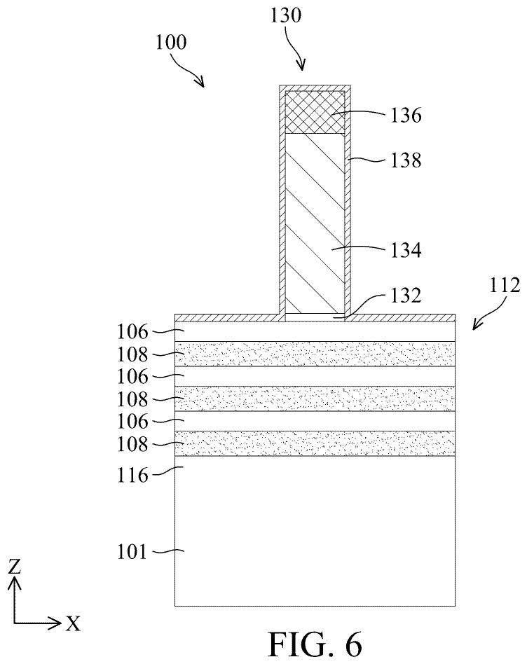

As shown in FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The portions of the fin structures 112 that are covered by the sacrificial gate electrode layer 134 of the sacrificial gate structure 130 serve as channel regions for the semiconductor device structure 100.

FIGS. 6-9 are cross-sectional side views of various stages of manufacturing the semiconductor device structure 100 taken along line A-A of FIG. 5, in accordance with some embodiments. As shown in FIG. 6, a first gate spacer 138 is deposited on the exposed surfaces of the semiconductor device structure 100. For example, the first gate spacer 138 is deposited on the fin structures 112, the isolation regions 120, and the sacrificial gate structure 130. The first gate spacer 138 may be made of a dielectric material such as silicon oxide, silicon nitride, silicon carbide, silicon oxynitride, SiCN, silicon oxycarbide, SiCON, and/or combinations thereof. In one embodiment, the first gate spacer 138 is SiCN or SiOC. The first gate spacer 138 may be formed by any suitable process. In some embodiments, the first gate spacer 138 is a conformal layer formed by a conformal process, such as an atomic layer deposition (ALD) process.

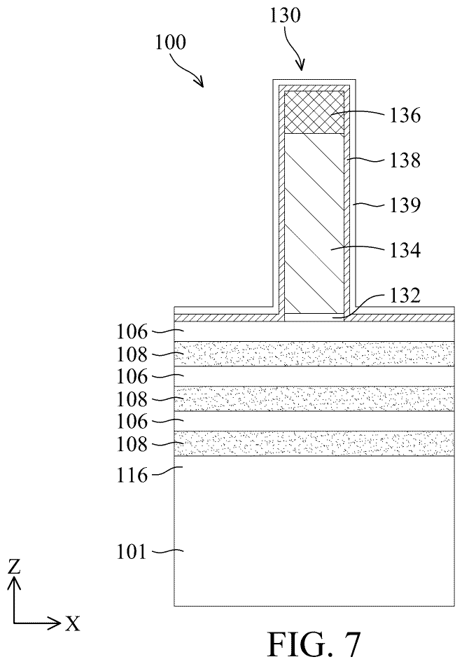

As shown in FIG. 7, a second gate spacer 139 is deposited on the first gate spacer 138. The second gate spacer 139 may include any suitable dielectric material, such as SiOₓ, SiON, SiN, SiCON, or SiCO. The first and second gate spacers 138, 139 may include the same material. In some embodiments, the first and second gate spacers 138, 139 may include a material that is chemically different from each other. For example, the first gate spacer 138 may be SiCN or SiOC and the second gate spacer 139 may be SiCON. The second gate spacer 139 may have a thickness ranging from about 0.5 nm to about 5 nm. The second gate spacer 139 may be formed by any suitable process. In some embodiments, the second gate spacer 139 is deposited by CVD, PECVD, or electron cyclotron resonance CVD (ECR-CVD). The plasma source may be inductively coupled plasma source or capacitively coupled plasmas source. The plasma power may range from about 100 W to about 500 W, and the processing temperature may range from about 100 degrees Celsius to about 600 degrees Celsius. In some embodiments, a layer is deposited, and a treatment process is performed to form the second gate spacer 139. For example, the layer, such as an amorphous silicon layer, a silicon carbide layer, a SiCN layer, or a SiCON layer, is first deposited on the first gate spacer 138, and the layer is then exposed to a treatment gas to form the second gate spacer 139. The treatment gas may be an oxygen-containing gas, a nitrogen-containing gas, or a combination thereof. In some embodiments, the treatment gas includes N₂O, NH₃, O₂, or a combination of N₂ and O₂.

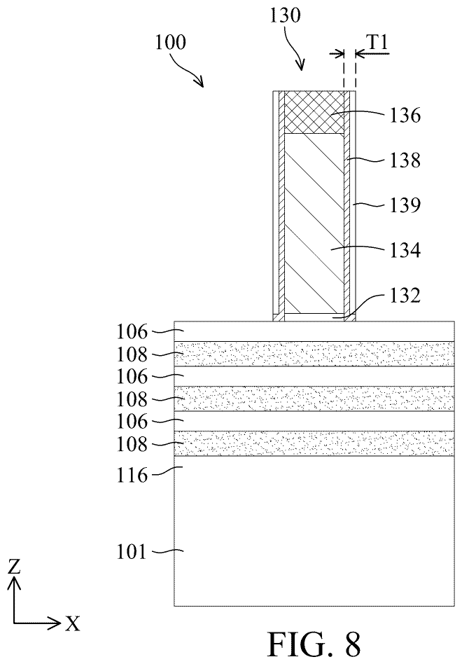

As shown in FIG. 8, horizontal portions of the first and second gate spacers 138, 139 are removed. In some embodiments, the horizontal portions of the first and second gate spacers 138, 139 are removed by an anisotropic etch process. The anisotropic etch process may be a selective etch process that does not substantially affect the mask layer 136, the stack of semiconductor layers 104, and the isolation regions 120. The first and second gate spacers 138, 139 may have a combined thickness T1 in a range of about 4 nm to about 10 nm. The thickness range is applicable to a single gate spacer (i.e., the first and second gate spacers 138, 139 are formed of the same material).

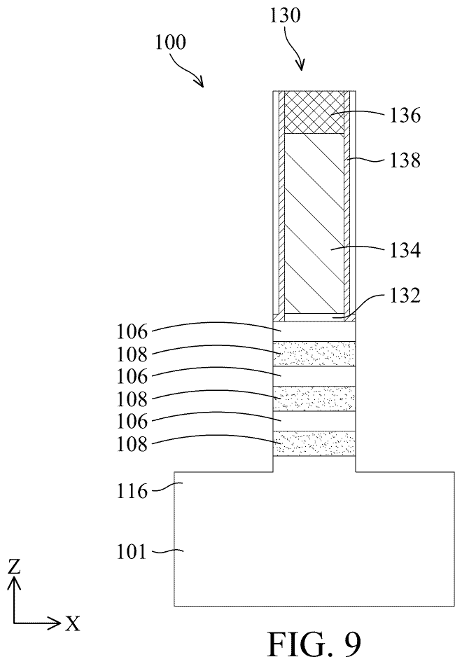

As shown in FIG. 9, the portions of the fin structures 112 not covered by the sacrificial gate structure 130 and the first and second gate spacers 138, 139 are recessed to a level above, at, or below the top surfaces of the isolation regions 120. The recess of the portions of the fin structures 112 can be done by an etch process. The etch process may be a dry etch, such as a RIE, NBE, or the like, or a wet etch, such as using tetramethyalammonium hydroxide (TMAH), ammonium hydroxide (NH₄OH), or any suitable etchant.

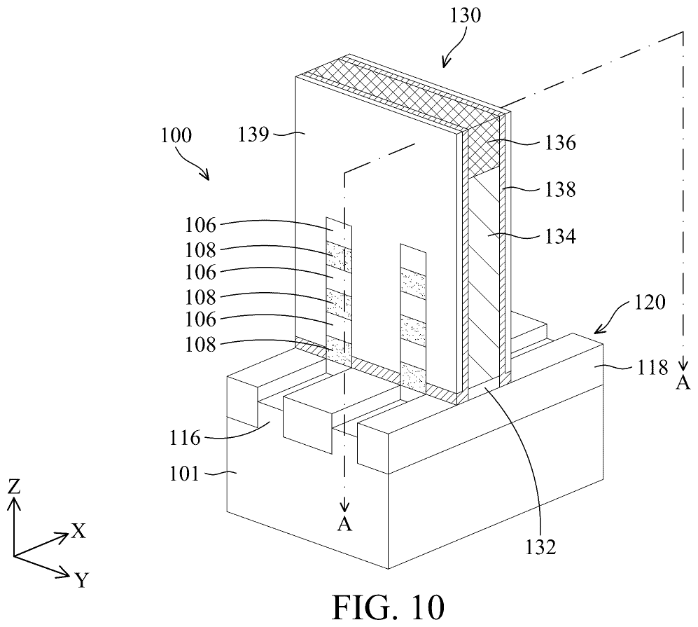

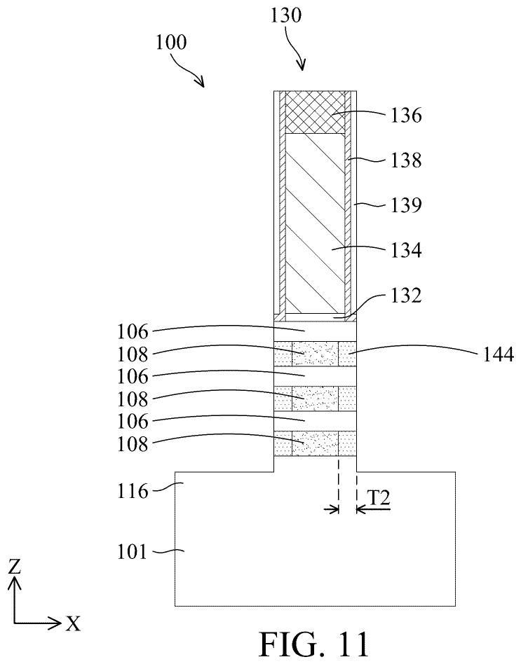

FIG. 10 is a perspective view of the semiconductor device structure 100 of FIG. 9, in accordance with some embodiments. FIGS. 11-20 are cross-sectional side views of various stages of manufacturing the semiconductor device structure taken along line A-A of FIG. 10, in accordance with some embodiments. As shown in FIG. 11, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144. The dielectric spacers 144 may be made of a low-K dielectric material, such as SiON, SiCN, SiOC, SiOCN, or SiN. In one embodiment, the dielectric spacer 144 includes SiONC. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction. The dielectric spacer 144 may have a thickness T2 in a range of about 4 nm to about 10 nm. In some embodiments, the thickness T2 of the dielectric spacer 144 and the combined thickness T1 of the first and second gate spacers 138, 139 may be different from each other.

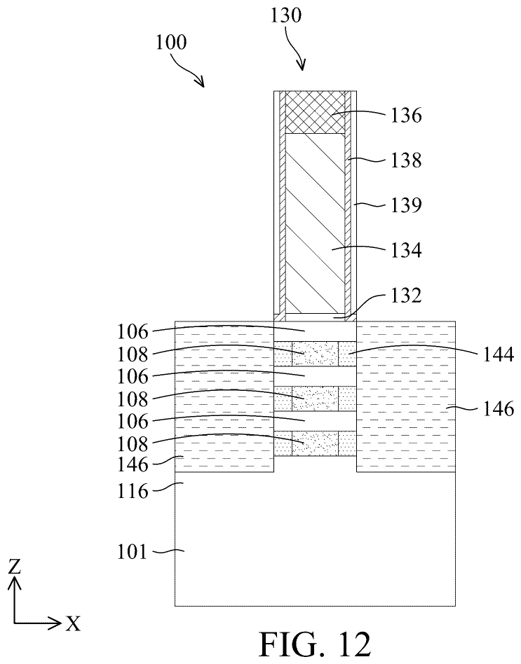

As shown in FIG. 12, source/drain (S/D) regions 146 are formed from the well portion 116. The S/D regions 146 may grow both vertically and horizontally to form facets, which may correspond to crystalline planes of the material used for the well portion 116. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE.

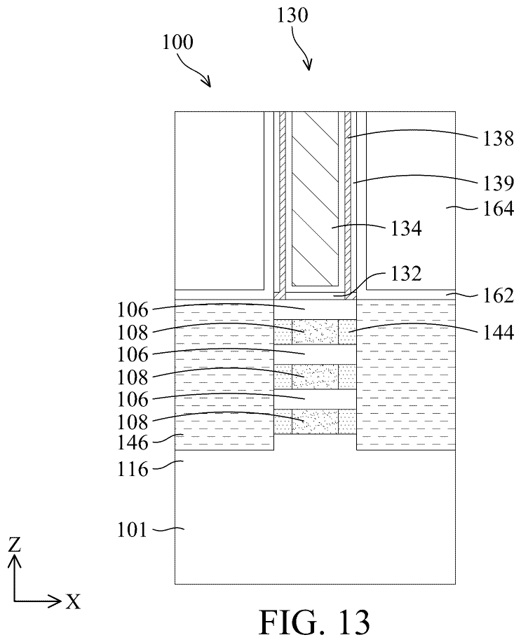

As shown in FIG. 13, a contact etch stop layer (CESL) 162 is conformally formed on the exposed surfaces of the semiconductor device structure 100. The CESL 162 covers the second gate spacer 139, the isolation regions 120, and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. In some embodiments, the CESL 162 is a single layer, as shown in FIG. 13. In some embodiments, the CESL 162 includes two or more layers. Next, an interlayer dielectric (ILD) layer 164 is formed on the CESL 162. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164.

After the ILD layer 164 is formed, a planarization operation, such as CMP, is performed on the semiconductor device structure 100 until the sacrificial gate electrode layer 134 is exposed, as shown in FIG. 13.

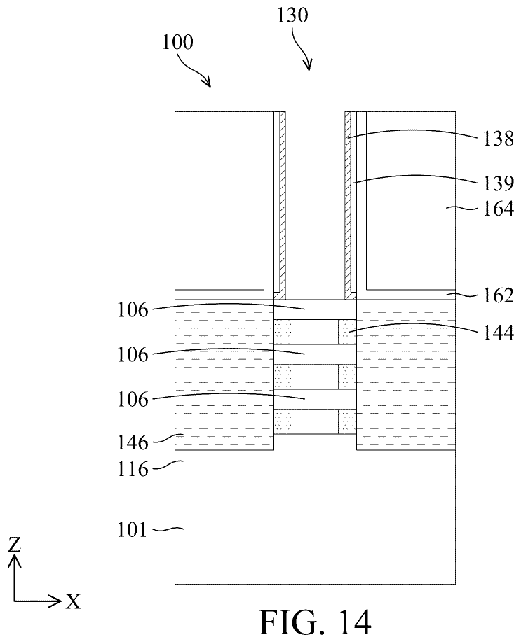

As shown in FIG. 14, the sacrificial gate structure 130 and the second semiconductor layers 108 are removed. The removal of the sacrificial gate structure 130 and the semiconductor layers 108 forms an opening between the first gate spacers 138 and an opening between the first semiconductor layers 106. The ILD layer 164 protects the S/D regions 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the first gate spacers 138, the ILD layer 164, and the CESL 162.

The second semiconductor layers 108 may be removed using dry etch, wet etch, or a combination thereof. In cases where the second semiconductor layers 108 are made of SiGe and the first semiconductor layers 106 are made of Si, the chemistry used in the selective wet etching process removes the SiGe while not substantially affecting Si, the dielectric materials of the first gate spacers 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), or phosphoric acid (H₃PO₄).

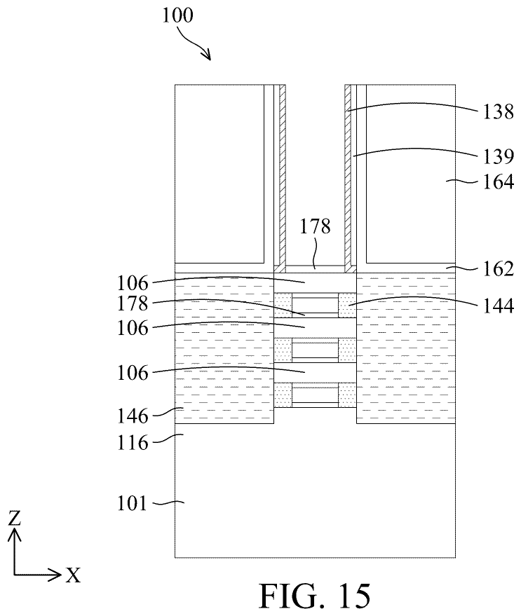

As shown in FIG. 15, an interfacial layer (IL) 178 is formed to surround exposed surfaces of the first semiconductor layers 106. The IL 178 may include or be made of an oxygen-containing material or a silicon-containing material, such as silicon oxide, silicon oxynitride, oxynitride, hafnium silicate, etc. In one embodiment, the IL 178 is silicon oxide. The IL 178 may be formed by CVD, ALD, a clean process, or any suitable process. The IL 178 may have a thickness of about 0.5 nm to about 1.5 nm.

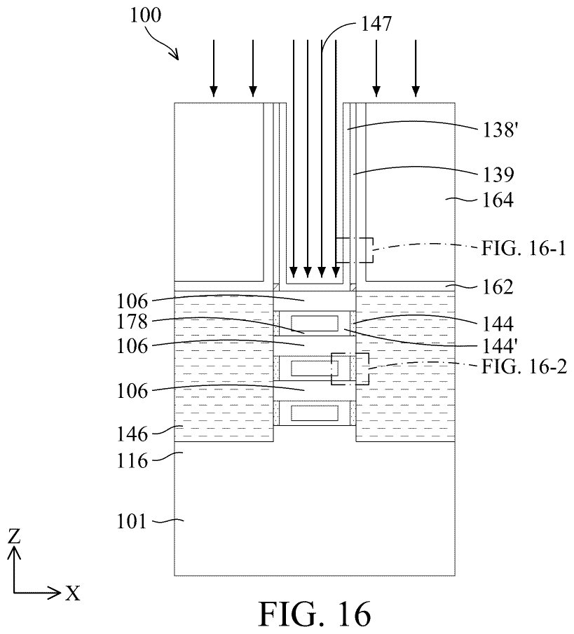

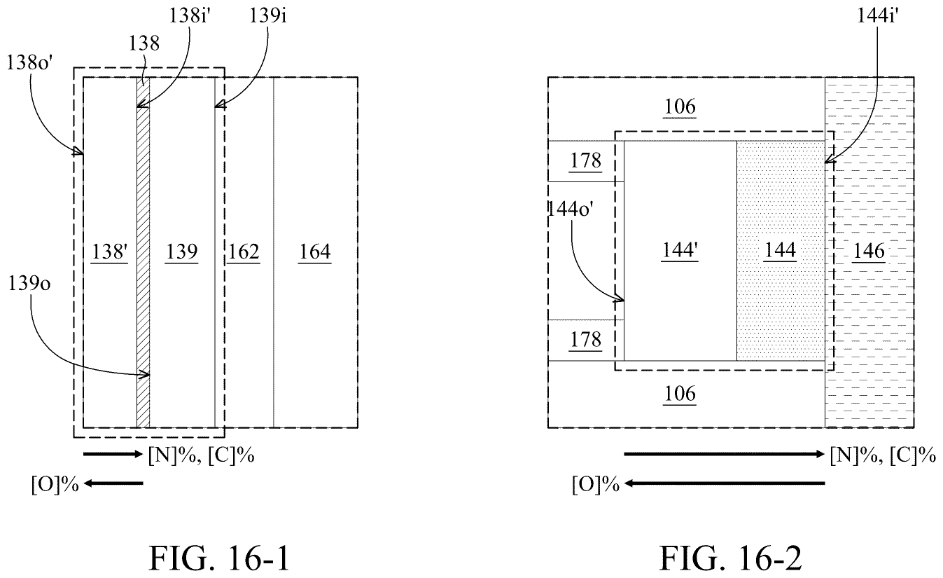

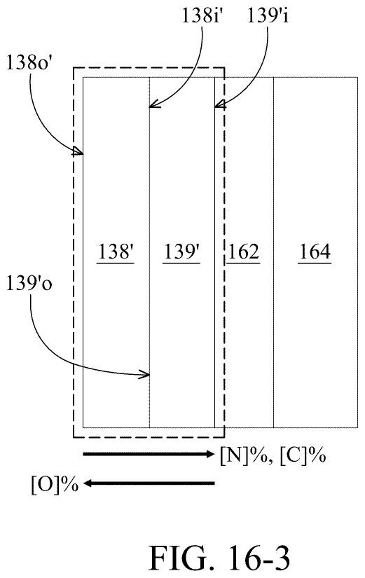

As shown in FIG. 16, portions of the first gate spacer 138 and the dielectric spacers 144 are oxidized by an oxidation process 147. The oxidation process 147 may be any suitable oxidation process that is capable of driving oxygen atoms or oxygen radicals of species into the first gate spacer 138 and the dielectric spacers 144 and converting portions of the first gate spacer 138 and the dielectric spacers 144 into oxidized first gate spacer 138′ and oxidized dielectric spacers 144′, respectively. For example, the oxidation process may use reactive species generated from oxygen-containing gases (e.g., O₂, H₂O, NO, or the like) in-situ in a reaction chamber or in the upstream of a reaction chamber (e.g., from a remote plasma generator). Exemplary reactive species may include oxygen plasma or neutral radical species of oxygen, such as oxygen radicals or atomic oxygen. In some embodiments, the first gate spacer 138 and the dielectric spacers 144 may be further exposed to H₂, N₂, NH₃, or the like, which may serve as dilution gas and/or to assist the oxidation process. Other suitable oxidation processes, such as a dry thermal oxidation process or a wet oxidation process, may also be used. In some exemplary embodiments where a wet oxidation process is adapted, the first gate spacer 138 and the dielectric spacers 144 may be exposed to water vapor or steam as the oxidant, at a pressure of about 1 Torr to about 40 ATM, within a temperature range of about 200 degrees Celsius to about 900 degrees Celsius, such as about 400 degrees Celsius to about 600 degrees Celsius, and for a time from about 1 minute to about 2 hours.

The temperature of the oxidation process 147 may cause the oxygen atoms or radicals to diffuse laterally and vertically in the first gate spacer 138 and the dielectric spacers 144. FIGS. 16-1 and 16-2 are enlarged views of a portion of the semiconductor device structure 100 showing an oxidation profile corresponding to the profile of the oxidized first gate spacer 138′ and oxidized dielectric spacers 144′, respectively. In the embodiments where the first gate spacer 138 is formed of SiCN, the nitrogen (N) or carbon (C) concentration is gradually decreased from an outer surface 1380′ to an inner surface 138i′ of the oxidized first gate spacer 138′, while the oxygen (O) concentration is gradually increased from the inner surface 138i′ to the outer surface 1380′ of the oxidized first gate spacer 138′, as shown in FIG. 16-1. In some embodiments, the oxidized first gate spacer 138′ has a first oxygen concentration and the first gate spacer 138 disposed between the oxidized first gate spacer 138′ and the second gate spacer 139 has a second oxygen concentration that is lower than the first oxygen concentration.

Likewise, in the embodiments where the dielectric spacers 144 is formed of SiCN or SiOCN, the nitrogen (N) or carbon (C) concentration is gradually decreased from an outer surface 1440′ to an inner surface 144i′ of the oxidized dielectric spacer 144′, while the oxygen (O) concentration is gradually increased from the inner surface 144i′ to the outer surface 1440′ of the oxidized dielectric spacer 144′, as shown in FIG. 16-2. In some embodiments, the oxidized dielectric spacer 144′ has a first oxygen concentration and the dielectric spacer 144 disposed between the oxidized dielectric spacer 144′ and the dielectric spacer 144 has a second oxygen concentration that is lower than the first oxygen concentration.

In some embodiments, the oxidized dielectric spacer 144′ has a first oxygen concentration and the oxidized first gate spacer 138′ has a second oxygen concentration that is greater than the first oxygen concentration.

In various embodiments, the oxidized first gate spacer 138′ and the dielectric spacers 144′ may have about 10 at. % or less of nitrogen, about 20 at. % or less of carbon, and about 35 at. % or more of oxygen after the oxidation process 147. In some embodiments, the oxidized first gate spacer 138′ may have an atomic percentage of oxygen increased from 15-20 at. % to about 35-65 at. % after the oxidation process 147. In some embodiments, the atomic percentage of carbon, nitrogen, and oxygen in the oxidized first gate spacer 138′ may be different than the atomic percentage of carbon, nitrogen, and oxygen in the oxidized dielectric spacers 144′. The high concentration of oxygen and low concentration of carbon and/or nitrogen will result in lower K value (e.g., 4.5 or below) of the oxidized first gate spacer 138′ and the dielectric spacers 144′. As a result, the parasitic capacitance is reduced and the overall device performance is improved.

In some embodiments, the oxidized portions of the first gate spacer 138 and the dielectric spacers 144 may include substantially the same material as the IL 178 after the oxidation process 147. In some embodiments, the IL 178 is further oxidized after the oxidation process 147, and IL 178, the oxidized first gate spacer 138′, and the oxidized dielectric spacers 144′ include substantially the same material.

In some alternative embodiments, the oxidation process 147 is performed so that the first gate spacer 138 is fully oxidized. In some embodiments, the oxidation process 147 is performed so that oxygen atoms or radicals are further diffused into the second gate spacer 139, turning a portion or entire second gate spacer 139 into an oxidized second gate spacer 139′. In such cases, the entire first gate spacer 138 is oxidized and the oxidized second gate spacer 139′ may follow the same oxidation profile as the oxidized first gate spacer 138′. In some embodiments, the as-deposited first gate spacer 138 includes SiCN and the oxidized first gate spacer 138′ after the oxidation process 147 includes SiO₂. In cases where the second gate spacer 139 is formed of SiCON, the nitrogen (N) or carbon (C) concentration is gradually decreased from an outer surface 1390′ to an inner surface 139i′ of the oxidized second gate spacer 139, while the oxygen (O) concentration is gradually increased from the inner surface 139i′ to the outer surface 1390′ of the oxidized second gate spacer 139′. FIG. 16-3 is an enlarged view of a portion of the semiconductor device structure 100 showing an oxidation profile corresponding to the profile of the oxidized first and second gate spacer 138′, 139′. In some embodiments, the oxidized first gate spacer 138′ may have an atomic percentage of oxygen increased from 15-20 at. % to about 35-65 at. %, and the oxidized second gate spacer 139′ may have an atomic percentage of oxygen increased from 5 at. % or less to about 20-65 at. %.

In some embodiments, the oxidized dielectric spacer 144′ has a first oxygen concentration and the oxidized second gate spacer 139′ has a second oxygen concentration that is greater than the first oxygen concentration. In some embodiments, the oxidized first gate spacer 138′ has a third oxygen concentration that is greater than the first and the second oxygen concentration.

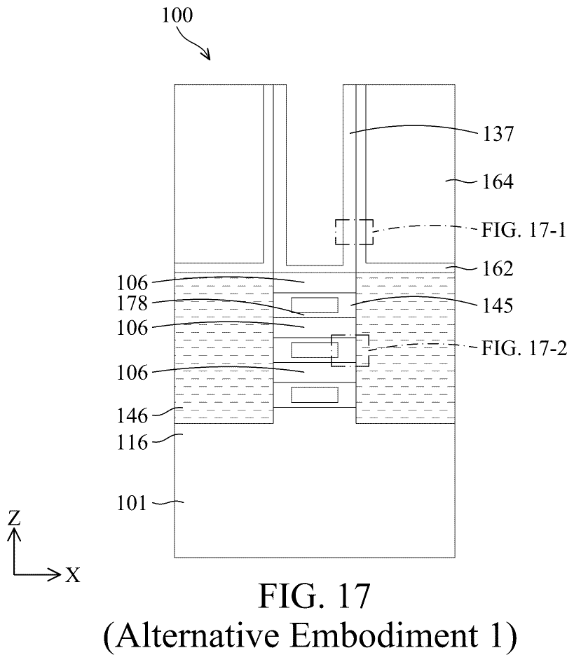

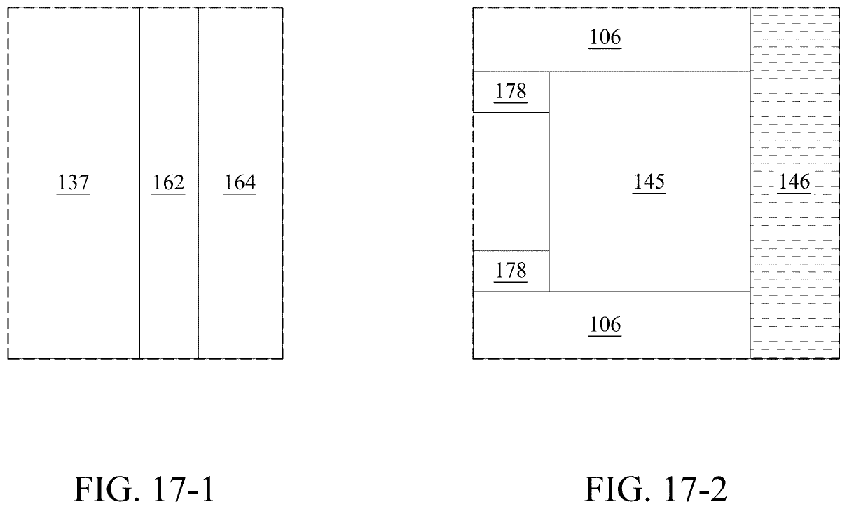

In some alternative embodiments, a single layer is used for the gate spacer (i.e., the first and second gate spacers 138, 139 include the same material), and both the gate spacer and the dielectric spacers 144 may be partially or fully oxidized after the oxidation process 147. FIG. 17 illustrates an embodiment in which a gate spacer 137 and dielectric spacers 145 are fully oxidized after the oxidation process 147. FIGS. 17-1 and 17-2 are enlarged views of a portion of the semiconductor device structure 100 showing the fully oxidized gate spacer 137 and dielectric spacers 145 in accordance with some embodiments. In some embodiments, the as-deposited gate spacer and dielectric spacers include SiCN or SiCON, and the oxidized gate spacer 137 and the dielectric spacers 145 after the oxidation process 147 include SiO₂, showing chemical bond conversion from Si—C—Si and Si—N—Si into Si—O—Si. In some embodiments, the gate spacer 137, the dielectric spacers 145, and the IL 178 include substantially the same material (e.g., silicon oxide) after the oxidation process 147. In such cases, the composition percentage of silicon oxide may be at a ratio [Si]: [O] of about 1:2. While the gate spacer 137 and the dielectric spacers 145 are fully or substantially oxidized, in some cases a traceable amount of nitrogen and carbon may still be detected in the gate spacer 137 and/or the dielectric spacers 145. For example, the gate spacer 137 may have an atomic percentage of nitrogen of about 1 at. % or less, and an atomic percentage of carbon of about 3 at. % or less. Likewise, the dielectric spacers 145 may have an atomic percentage of nitrogen of about 1 at. % or less, and an atomic percentage of carbon of about 3 at. % or less.

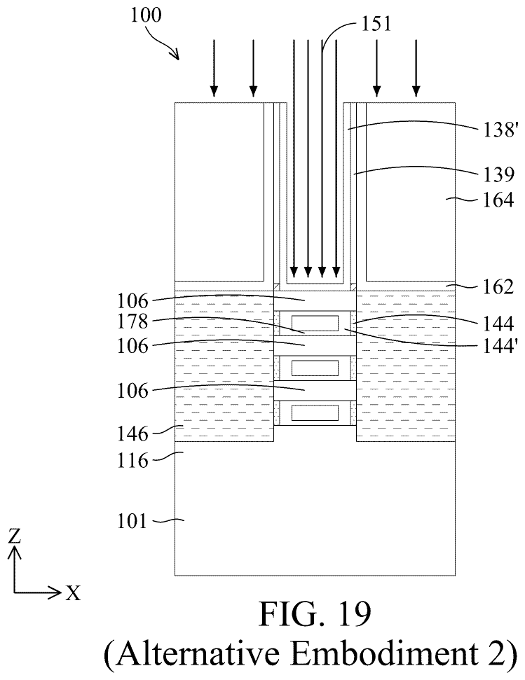

In some alternative embodiments, after formation of the IL 178, the semiconductor device structure 100 is subjected to an ion implantation process 149. Particularly, the ion implantation process 149 is performed so that majority of the ion species (dopants) are implanted into the first gate spacer 138, the IL 178, and the dielectric spacers 144. The implanted regions of the first gate spacer 138, the IL 178, and the dielectric spacers 144 are then oxidized (FIG. 19) to form dielectric or oxidized regions. The ion implantation process 149 changes material properties of the first gate spacer 138, the IL 178, and the dielectric spacers 144 so that the implanted regions can be oxidized at a faster rate. For example, the implanted dopants may be selected to increase oxidation rate of the implanted regions by transforming the implanted region into an amorphous state. Additionally or alternatively, the implanted dopants may be selected to decrease temperature of the subsequent oxidation process, which in turn increases the reaction rate of the oxidation process. Additionally or alternatively, the implanted dopants may be selected to promote oxidation of the implanted regions while preventing loss of the dielectric regions during the subsequent gate replacement process.

The ion implantation process 149 may employ one or more ion species. In some embodiments, the ion implantation process 149 employs a first group of ion species (“Group 1”) comprising fluorine (F) or atoms having an atomic radius of about 0.5 times to about 1.5 times the atomic radius of silicon, a second group of ion species (“Group 2”) comprising inert gas, such as neon (Ne), argon (Ar), krypton (Kr), xenon (Xe), or any combination thereof, and a third group of ion species (“Group 3”) comprising oxygen (O). The first group of ion species (e.g., F) may be employed to promote growth of oxides on the first gate spacer 138, the IL 178, and the dielectric spacers 144 when implanted with F ion species. The second group of ion species (e.g., Ar) may be employed to lower the activation energy of oxygen and promote chemical reaction between the implanted ions and the first gate spacer 138, the IL 178, and the dielectric spacers 144. As a result, the oxidation rate of the implanted regions is increased. The third group of ion species may be employed to provide oxygen into the implanted regions which enhances oxidation of the first gate spacer 138, the IL 178, and the dielectric spacers 144.

The ion implantation process 149 may be a zero-degree tilt implantation process performed at a low-temperature range (e.g., 25 degrees Celsius to about 150 degrees Celsius). While various ion species may distribute over the implanted region in both lateral and vertical directions, the implant dosage and ion kinetic energy for each group of ion species may be selected to achieve desired implant concentration profile in the target regions. The ion species of each group may be implanted at a kinetic energy in a range of about 0.3 KeV to about 10 KeV, such as about 0.5 KeV to about 5 KeV, and an implant dosage of each group of ion species may be in a range of about 1E10¹² atoms/cm² to about 3E10²² atoms/cm², such as about 1E10¹⁶ atoms/cm² to about 6E1015 atoms/cm², which may vary depending on the mass and intended purpose of the ions.

In some embodiments, an annealing process may be performed to oxidize the implanted regions. The annealing process may be controlled to have minimum impacts on the implanted regions which are in an amorphous state. In some embodiments, the anneal process is RTA which heats the semiconductor device structure 100 to a target temperature range of about 600 degrees Celsius to about 1200 degrees Celsius. The annealing process may be performed in an ambient comprising O₂, H₂O, NO, H₂, N₂, NH₃, Ar, He, or the like, or any combination thereof, and at a pressure of about 1 Torr to about 40 ATM. The annealing process may cause the implanted ion species to diffuse further into the first gate spacer 138, the IL 178, and the dielectric spacers 144.

As shown in FIG. 19, after the ion implantation process 149, the semiconductor device structure 100 is subjected to an oxidation process 151 to further oxidize and transform the implanted region into dielectric or oxidized regions (e.g., oxidized first gate spacer 138′ and oxidized dielectric spacers 144′). During the oxidation process, the implanted region may be partially or fully oxidized. The implanted regions are oxidized at a faster rate due to the chemical/physical effects provided by the implanted ion species. The oxidation process may be the oxidation process 147 discussed above or any suitable oxidation process.

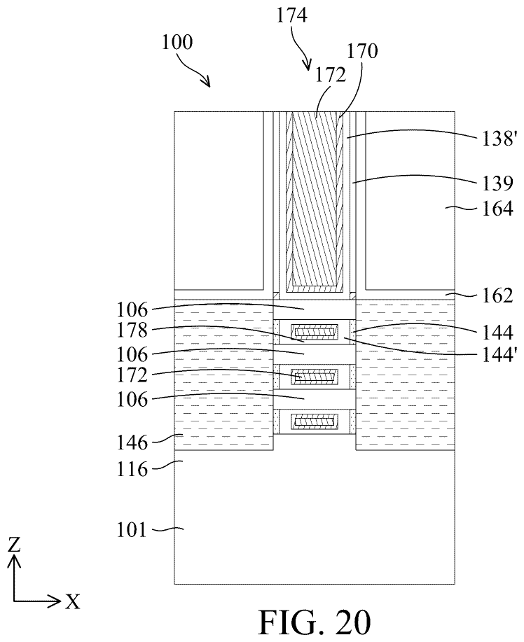

As shown in FIG. 20, after the oxidation process 147, a gate dielectric layer 170 is formed on the IL 178 and surround the exposed portions of the first semiconductor layers 106, and a gate electrode layer 172 is formed over the gate dielectric layer 170. The gate dielectric layer 170 and the gate electrode layer 172 may be collectively referred to as a gate structure 174. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HTIO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAIN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the ILD layer 164. The gate dielectric layer 170 and the gate electrode layer 172 formed over the ILD layer 164 are then removed by using, for example, CMP, until the top surface of the ILD layer 164 is exposed.

It is understood that the semiconductor device structure 100 may undergo further processes to form conductive contacts in the ILD layer 164 to be electrically connected to the S/D regions 164 and to form conductive contacts to be electrically connected to the gate electrode layer 172. An interconnect structure may be formed over the semiconductor device structure 100 to provide electrical paths to the devices formed on the substrate 101.

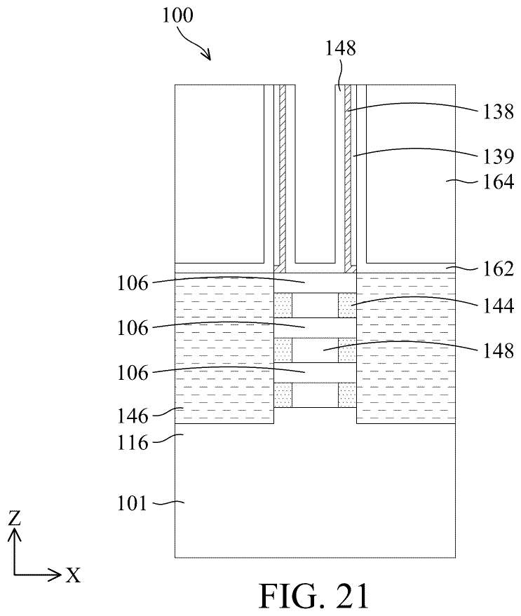

FIGS. 21-26 are cross-sectional side views of various stages of manufacturing the semiconductor device structure taken along line A-A of FIG. 5, in accordance with some alternative embodiments. After the sacrificial gate structure 130 and the second semiconductor layers 108 are removed (e.g., FIG. 14), a dummy hard mask layer 148 is formed on exposed surfaces of the first gate spacer 138, the first semiconductor layers 106, and the dielectric spacers 144. The dummy hard mask layer 148 also fills the opening between the first semiconductor layers 106. The dummy hard mask layer 148 protects the dielectric spacers 144 from being oxidized at the subsequent oxidation process. The hard mask layer 148 may include an oxide, a nitride, a dielectric, or any combination thereof, and may be formed by CVD, PECVD, ALD, or any suitable deposition technique. In some embodiments, the hard mask layer 148 is formed of a material different than that of the first gate spacer 138. In some embodiments, the hard mask layer 148 may be formed of a material having an etch selectivity relative to the dielectric spacers 144.

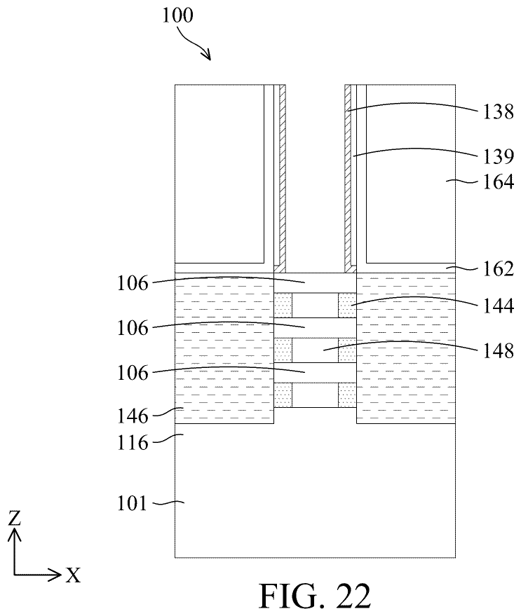

In FIG. 22, the dummy hard mask layer 148 on the first gate spacer 138 is removed. The dummy hard mask layer 148 may be removed using any suitable etch process. The etch process may be time controlled so that the dummy hard mask layer 148 on the first gate spacer 138 is removed without substantially affecting the dummy hard mask layer 148 between the first semiconductor layers 106. The first gate spacer 138 is exposed after the etch process.

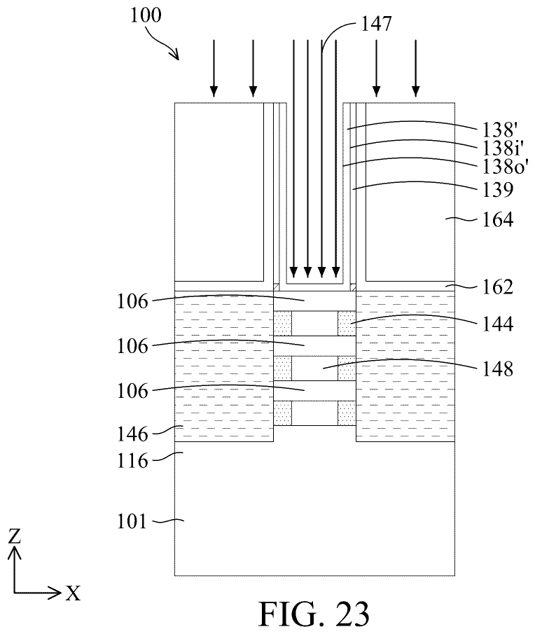

In FIG. 23, the first gate spacer 138 is subjected to an oxidation process, such as the oxidation process 147 as discussed above. The first gate spacer 138 may be partially oxidized or fully oxidized in a similar fashion as discussed above with respect to FIGS. 16-1, 16-3, and 17. A portion of the exposed surface of the topmost first semiconductor layer 106 may also be oxidized after the oxidation process 147. Additionally or alternatively, a thin oxide layer may be formed on the exposed surface of the topmost first semiconductor layer 106 after the oxidation process 147. FIG. 23 illustrates an embodiment where the first gate spacer 138 is fully oxidized to become oxidized first gate spacer 138′. Likewise, the oxidized first gate spacer 138′ may have an oxidation profile corresponding to the profile of the oxidized first gate spacer 138′ discussed above with respect to FIGS. 16-1, 16-3, and 17. In the embodiments where the first gate spacer 138 is formed of SiCN, the nitrogen (N) or carbon (C) concentration is gradually decreased from an outer surface 1380′ to an inner surface 138i′ of the oxidized first gate spacer 138′, while the oxygen (O) concentration is gradually increased from the inner surface 138i′ to the outer surface 1380′ of the oxidized first gate spacer 138′.

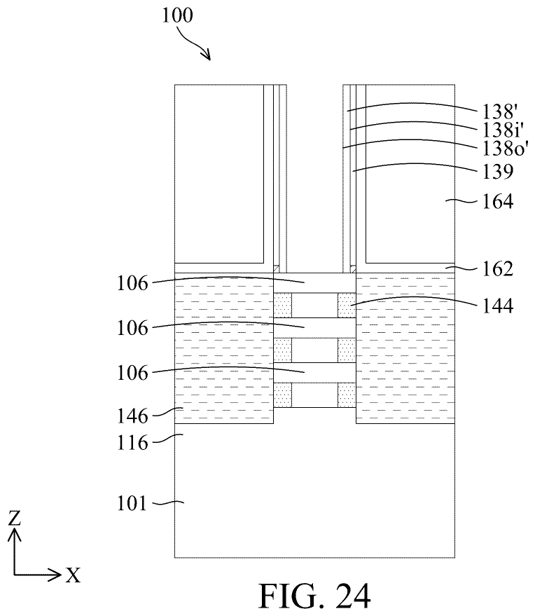

In FIG. 24, the dummy hard mask layer 148 between the first semiconductor layers 106 is removed. The dummy hard mask layer 148 may be removed by an etch process which uses an etchant that selectively removes the dummy hard mask layer 148 without substantially affecting the oxidized first gate spacer 138′, the dielectric spacers 144, and the first semiconductor layers 106. The etch process may be anisotropic so that the dummy hard mask layer 148 on the exposed surface of the topmost first semiconductor layer 106 is also removed.

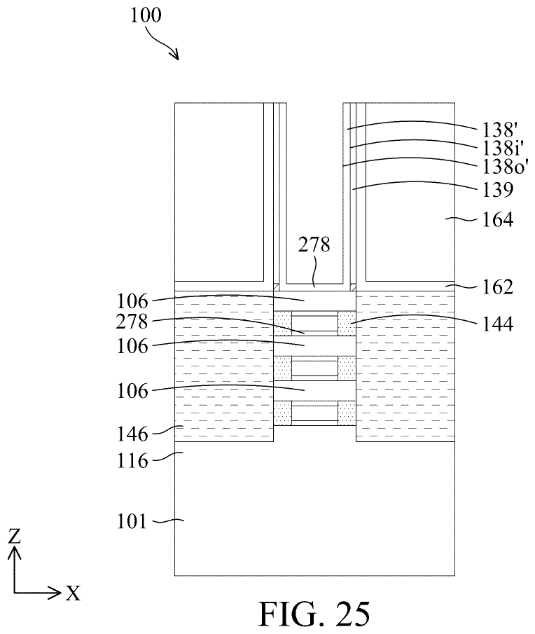

In FIG. 25, an interfacial layer (IL) 278, such as the IL 178, is formed to surround exposed surfaces of the first semiconductor layers 106. The IL 278 may be formed in a similar fashion to the IL 178 as discussed above with respect to FIG. 15.

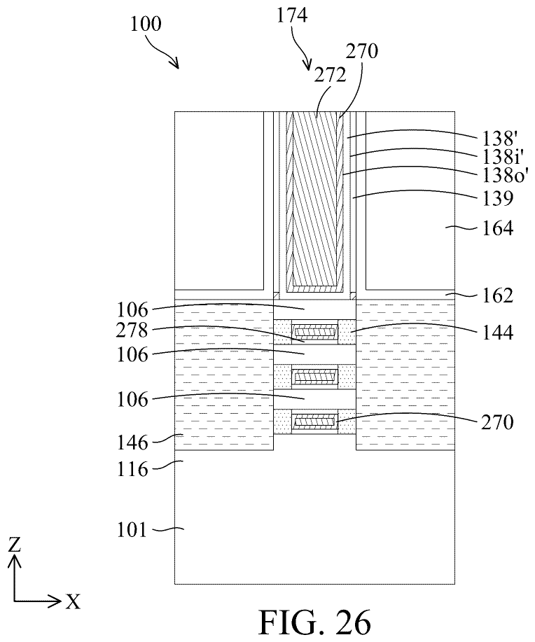

In FIG. 26, a gate dielectric layer 270, such as the gate dielectric layer 170, is formed on the IL 278 and surround the exposed portions of the first semiconductor layers 106, and a gate electrode layer 272, such as the gate electrode layer 172, is formed over the gate dielectric layer 270. The gate dielectric layer 270 and the gate electrode layer 272 may be formed in a similar fashion to the gate dielectric layer 170 and the gate electrode layer 172 as discussed above with respect to FIG. 20. As such, the first and second gate spacers 138, 139 are partially or fully oxidized while the material of the dielectric spacers 144 remain substantially unchanged before and after the oxidation process.

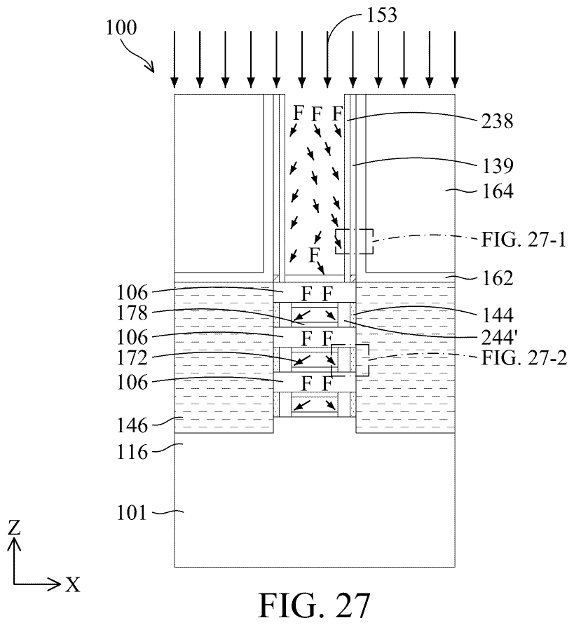

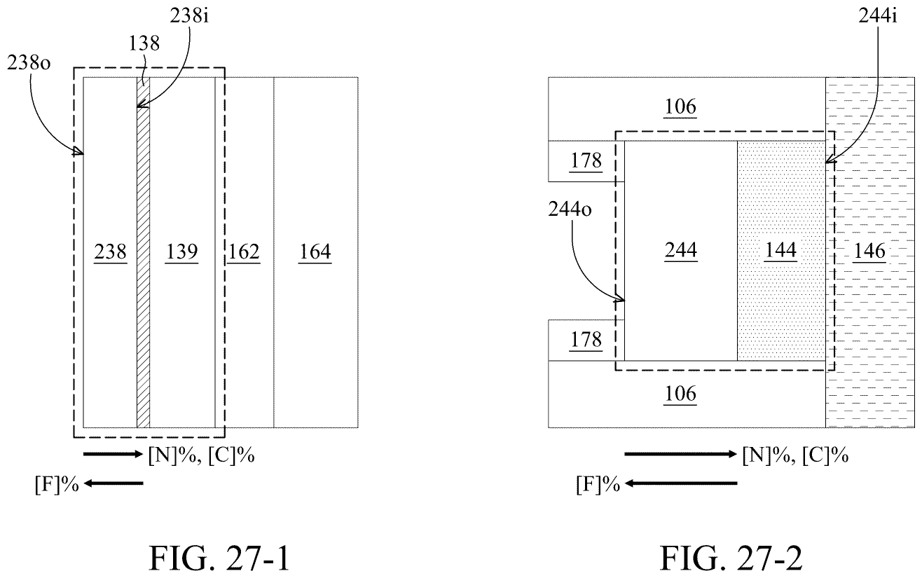

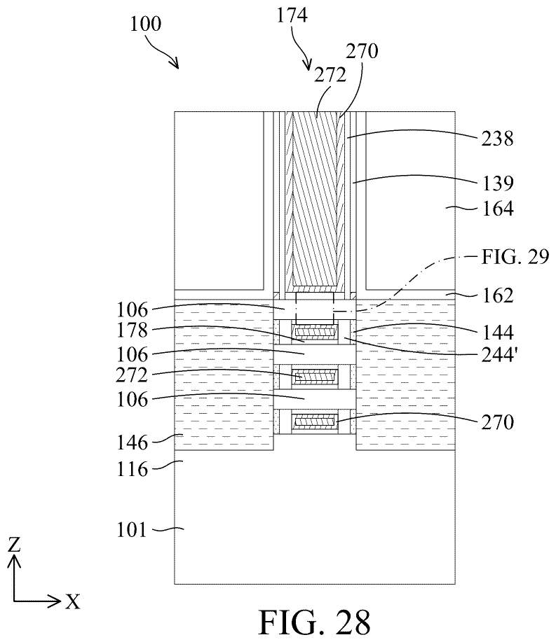

FIGS. 27-28 are cross-sectional side views of various stages of manufacturing the semiconductor device structure taken along line A-A of FIG. 5, in accordance with some alternative embodiments. After the IL 178 is formed (e.g., FIG. 15), portions of the first gate spacer 138 and the dielectric spacers 144 are fluorinated by a fluorination process 153 and converted into fluorinated first gate spacer 238 and fluorinated dielectric spacers 244. The fluorination process 153 may be any suitable fluorination process. In some embodiments, the fluorination process is a fluorine soak process. The fluorine soak process may include exposing the first gate spacer 138 and the dielectric spacers 144 to a fluorine-containing precursor at a processing temperature less than about 100 degrees Celsius. In some embodiments, the fluorine-containing precursor includes HF, CF₄, F₂, C₂F₆, a combination of HF and F₂, or other suitable fluorine-containing precursor. The processing temperature may range from about 20 degrees Celsius to about 250 degrees Celsius, and a processing pressure may range from about 0.1 torr to about 10 torr. The first gate spacer 138 and the dielectric spacers 144 may be exposed to the fluorine-containing precursor for a duration ranging from about 15 seconds to about 30 minutes. In some embodiments, the fluorine-containing precursor is F₂, and the first gate spacer 138 and the dielectric spacers 144 may be exposed to the F₂ for a duration ranging from about 5 minutes to about 20 minutes.

Alternatively, the fluorination process may be performed by exposing the first gate spacer 138 and the dielectric spacers 144 to reactive species generated from fluorine-containing precursor (e.g., F₂) in-situ in a reaction chamber or in the upstream of a reaction chamber (e.g., from a remote plasma generator). Exemplary reactive species may include fluorine plasma or neutral radical species of fluorine, such as fluorine radicals or atomic fluorine.

In some embodiments, a plasma treatment process may be performed on the as-deposited first gate spacer 138 and the dielectric spacers 144 prior to the fluorination process. The plasma treatment process includes exposing the first gate spacer 138 and the dielectric spacers 144 to a hydrogen-containing plasma. The hydrogen-containing plasma may be formed by activating a hydrogen-containing gas by a low power plasma source or a remote plasma source. The hydrogen-containing gas may be any suitable hydrogen-containing gas. In some embodiments, the hydrogen-containing gas is hydrogen gas (H₂). In some embodiments, the low power plasma source is a capacitively coupled plasma source, and the plasma power ranges from about 10 W to about 250 W. The plasma generated by the capacitively coupled plasma source or the remote plasma source includes more hydrogen radicals than ions. In addition, the processing temperature of the plasma treatment process is relatively low, such as from about 20 degrees Celsius to about 100 degrees Celsius. As a result, the hydrogen radicals replace the methyl terminal groups or are attached to the dangling Si bonds to form Si—H bonds. The plasma treatment process allows more Si—H bonds to be generated so that the subsequent fluorination process may be performed with relatively low energy, such as at a low temperature (e.g., about 150 degrees Celsius or below) without plasma. Low energy fluorination process may avoid causing the fluorine-containing precursor to become an etchant.

After the fluorination process 153, the fluorinated first gate spacer 238 and dielectric spacers 244 may include about 2 at. % to about 20 at. % of fluorine, for example about 10 at. % or less of fluorine. FIGS. 27-1 and 27-2 are enlarged views of a portion of the semiconductor device structure 100 showing a fluorination profile corresponding to the profile of the fluorinated first gate spacer 238 and fluorinated dielectric spacers 244, respectively. As shown in FIG. 27-1, the fluorinated first gate spacer 238 has an outer surface 2380 and an inner surface 238i. The concentration of fluorine decreases from the outer surface 2380 to the inner surface 238i, because the outer surface 2380 is exposed to the fluorine-containing precursors. In some embodiments, the fluorinated first gate spacer 238 has a first fluorine concentration and the first gate spacer 138 disposed between the fluorinated first gate spacer 238 and the second gate spacer 139 has a second fluorine concentration that is lower than the first fluorine concentration. In some cases, the first gate spacer 138 is not fluorinated and thus has little or no fluorine.

Likewise, the fluorinated dielectric spacer 244 has an outer surface 2440 and an inner surface 244i, and the concentration of fluorine decreases from the outer surface 2440 to the inner surface 244i. The fluorinated dielectric spacer 244 may have a first fluorine concentration and the dielectric spacer 144 between the fluorinated dielectric spacer 244 and the S/D region 146 may have a second fluorine concentration that is lower than the first fluorine concentration. In some cases, the dielectric spacer 144 is not fluorinated and thus has little or no fluorine.

In some embodiments, each of the fluorinated dielectric spacers 244 may include a fluorine concentration smaller than the fluorine concentration of the fluorinated first gate spacer 238.

The K value of the fluorinated first gate spacer 238 and the dielectric spacer 244 may be increased by about 0.1 to about 0.5. Therefore, leakage current is reduced and thermal stability is improved. In some embodiments, the fluorinated first gate spacer 238 and the dielectric spacer 244 may be formed of the same or different material (e.g., SiCN or SiCON) and may include about 2 at. % to about 20 at. % of carbon, and about 0 at. % to about 20 at. % of nitrogen. In cases where the fluorinated first gate spacer 238 and the dielectric spacer 244 include oxygen, the atomic percentage of oxygen may be about 15 at. % to about 35 at. %. In some embodiments, the carbon, nitrogen, and oxygen compositions may have no significant gradient in the fluorinated first gate spacer 238. However, the dielectric spacer 244 may have a concentration gradient of fluorine in which the fluorine concentration closer to the S/D regions 146 is relatively lower. In some embodiments, the atomic percentage of carbon, nitrogen, and oxygen in the fluorinated first gate spacer 238 may be different than the atomic percentage of carbon, nitrogen, and oxygen in the fluorinated dielectric spacers 244. The above atomic percentage range is also applicable to a single gate spacer (i.e., the first and second gate spacers 138, 139 are formed of the same material).

The remaining first gate spacer 138 and/or the second gate spacer 139 may function as a capping layer for the fluorinated first gate spacer 238. Likewise, the remaining dielectric spacer 144 may function as a capping layer for the fluorinated dielectric spacers 244. Subsequent processes, such as etching or epitaxial growth processes may cause the fluorine in the fluorinated first gate spacer 238 and the dielectric spacers 244 to be released, which may damage the exposed surfaces of the semiconductor device structure 100.

In some embodiments, one or more processes are optionally performed to further incorporate fluorine into the second gate spacer 139. The second gate spacer 139 may not fully fluorinated so as to maintain the mechanical strength of the second gate spacer 139. In addition, subsequent processes, such as etching and thermal processes may cause the fluorine in the second gate spacer 139 to be released, which may damage the exposed surfaces of the semiconductor device structure 100. In cases where the second gate spacer 139 is fluorinated, the CESL 162 may also function as a capping layer for the fluorinated second gate spacer 139. The one or more processes to incorporate fluorine into the second gate spacer 139 may be the same as or different from the one or more processes used to incorporate fluorine into the first gate spacer 138. In some embodiments, the plasma treatment process and the fluorination process described above with respect to FIG. 27 are performed to fluorinate the second gate spacer 139. In some embodiments, the fluorination process with higher energy is performed to fluorinate the second gate spacer 139 without the plasma treatment process. In some embodiments, the first gate spacer 138 is fluorinated by the fluorination process with higher energy without the plasma treatment process, and the second gate spacer 139 is fluorinated by the plasma treatment process and the fluorination process described in FIG. 27. A small portion of the first gate spacer 138 may be removed by the fluorine during the fluorination process with higher energy, and the other components of the semiconductor device structure 100 are protected by the first gate spacer 138. Components of the semiconductor device structure 100 are exposed during the fluorination of the second gate spacer 139. Thus, the plasma treatment process and the fluorination with low energy are performed to fluorinate the second gate spacer 139 in order to protect other components of the semiconductor device structure 100. In other words, in some embodiments, the first and second gate spacers 138, 139 are fluorinated using different processes in order to protect other components of the semiconductor device structure 100.

In some embodiments, the fluorination of the first gate spacer 138, the second gate spacer 139, and/or the dielectric spacers 144 may be enhanced by keeping the fluorinated layers in nitrogen environment immediately after the fluorination process, exposing the fluorinated layers in a water-free environment immediately after the fluorination process, and forming a capping layer on the fluorinated layers immediately after the fluorination process. For example, after the fluorination process 153, the semiconductor device structure 100 may be transferred to another chamber/system for subsequent processes (e.g., forming the gate dielectric layer 270) in a container that is charged with nitrogen. The subsequent process is free of water. In other words, no wet etching process may be performed immediately after the fluorination process. Immediately after the fluorination process 153, the gate dielectric layer 270, which functions as a capping layer for the fluorinated first gate spacer 238 and the dielectric spacers 244, is formed on the fluorinated first gate spacer 238 and the dielectric spacers 244. With these enhancements, the fluorine concentration in the fluorinated layers is substantially higher compared to fluorinated layers without the enhancements.

In FIG. 28, a gate dielectric layer 270, such as the gate dielectric layer 170, is formed on the IL 178 and surround the exposed portions of the first semiconductor layers 106, and a gate electrode layer 272, such as the gate electrode layer 172, is formed over the gate dielectric layer 270. The gate dielectric layer 270 and the gate electrode layer 272 may be formed in a similar fashion to the gate dielectric layer 170 and the gate electrode layer 172 as discussed above with respect to FIG. 20.

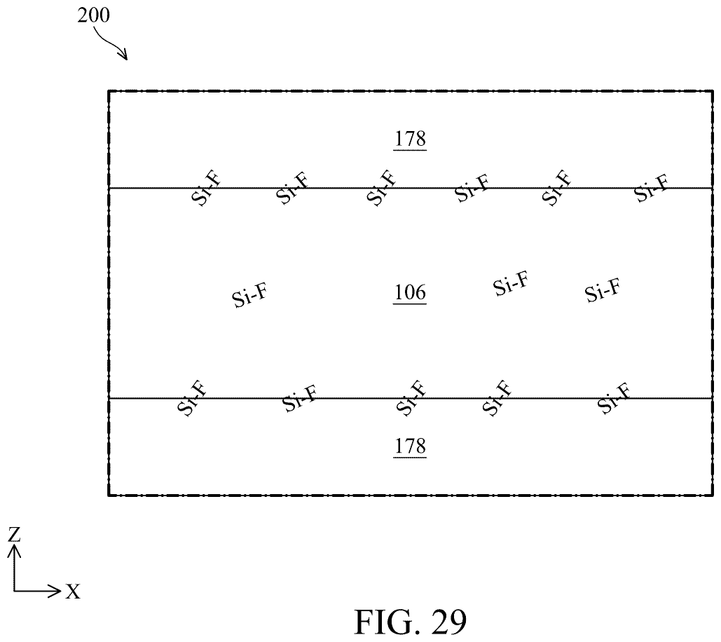

FIG. 29 illustrates a portion 200 of the semiconductor device structure 100 of FIG. 28, in accordance with some embodiments. In some embodiments, the IL 178 may be also fluorinated by the processes described in FIGS. 27, and the fluorine may diffuse to the interface between the IL 178 and the first semiconductor layer 106 and form Si—F bonds. In some embodiments, the fluorine has a first concentration at the interface between the IL 178 and the first semiconductor layer 106, and a second concentration between a top surface and a bottom surface of the first semiconductor layer 106, wherein the first concentration is greater than the second concentration. Fluorine can repair defects at the interface between the IL 178 and the first semiconductor layer 106. In some embodiments, the fluorine replaces oxygen vacancies at the interface between the IL 178 and the first semiconductor layer 106, which in turn improves interfacial state density (Dit).

Embodiments of the present disclosure provide semiconductor device structures having fully or partially oxidized gate spacers and oxidized dielectric spacers between channel layers. In some alternative embodiments, the gate spacers and the dielectric spacers are fluorinated. The increased oxygen or fluorine content in the oxidized or fluorinated gate spacers and dielectric spacers leads to decrease of the mechanical strength of the gate spacers and the dielectric spacers and therefore reduced dielectric constant (K) value of the gate spacers and the dielectric spacers. As a result, leakage current is reduced, and thermal stability as well as parasitic capacitance are improved.

An embodiment is a method for forming a semiconductor device structure. The method includes forming a sacrificial gate structure and a gate spacer structure over a portion of a fin structure formed over a substrate, the fin structure comprising a plurality of first semiconductor layers and a plurality of second semiconductor layers alternatingly stacked, removing portions of the fin structure to expose a portion of the substrate, recessing edge portions of each of the second semiconductor layers to form cavities and forming dielectric spacers in the cavities, forming source/drain regions on opposite sides of the sacrificial gate structure from the exposed portion of the substrate, removing the sacrificial gate structure and the second semiconductor layers to expose the gate spacer structure and the dielectric spacers, subjecting the gate spacer structure and the dielectric spacers to an oxidation process to form an oxidized gate spacer structure and oxidized dielectric spacers, wherein the oxidized gate spacer structure and the oxidized dielectric spacers each have an oxygen concentration that decreases from an inner surface facing a gate region towards an outer surface, and forming a gate dielectric layer and a gate electrode layer over the oxidized gate spacer structure and surrounding the first semiconductor layers.

Another embodiment is a method for forming a semiconductor device structure. The method includes forming a sacrificial gate structure and a gate spacer over a portion of a fin structure formed over a substrate, the fin structure comprising a plurality of first semiconductor layers and a plurality of second semiconductor layers alternatingly stacked. The method also includes removing portions of the fin structure to expose a portion of the substrate, removing a portion of each of the second semiconductor layers and replacing it with a dielectric spacer, forming a source/drain region on opposite sides of the sacrificial gate structure, removing the sacrificial gate structure and the second semiconductor layers to expose the gate spacer and dielectric spacers, subjecting the gate spacer and the dielectric spacers to an oxidation process so that portions of the gate spacer are oxidized, and forming a gate dielectric layer and a gate electrode layer over the oxidized gate spacer.

A further embodiment is a method. The method includes forming a sacrificial gate structure over a fin structure comprising a first plurality of semiconductor layers and a second plurality of semiconductor layers alternatingly stacked over a substrate, depositing a gate spacer structure on the sacrificial gate structure, the gate spacer structure comprising a first gate spacer adjacent to the sacrificial gate structure and a second gate spacer over the first gate spacer, removing portions of the fin structure to expose a portion of the substrate, recessing the second plurality of semiconductor layers to form cavities and forming dielectric spacers in the cavities, forming source/drain regions from the exposed portion of the substrate, removing the sacrificial gate structure and the second plurality of semiconductor layers to expose the first plurality of semiconductor layers, the gate spacer structure, and the dielectric spacers, forming an interfacial layer on a portion of each of the first plurality of semiconductor layers, and incorporating fluorine into the first gate spacer, the second gate spacer, and the dielectric spacers to form fluorinated first gate spacer, fluorinated second gate spacer, and fluorinated dielectric spacers, wherein the fluorinated first gate spacer has a higher fluorine concentration than the fluorinated second gate spacer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a gate dielectric layer disposed over a substrate;
a gate electrode layer disposed over the gate dielectric layer;
a plurality of semiconductor layers vertically stacked over the substrate, wherein the gate electrode layer surrounds a portion of each of the semiconductor layers;
a first gate spacer disposed adjacent the gate dielectric layer, wherein the first gate spacer comprises an inner surface facing the gate dielectric layer and an outer surface opposite the inner surface, and the first gate spacer includes an oxygen concentration that decreases from the inner surface towards the outer surface; and
a dielectric spacer disposed between two adjacent semiconductor layers of the plurality of semiconductor layers, wherein the dielectric spacer comprises an inner surface facing the gate dielectric layer and an outer surface opposite the inner surface, and the dielectric spacer includes an oxygen concentration that decreases from the inner surface towards the outer surface.

2. The semiconductor device structure of claim 1, further comprising:
a second gate spacer disposed on the outer surface of the first gate spacer, wherein the second gate spacer comprises an inner surface in contact with the outer surface of the first gate spacer and an outer surface opposite the inner surface, and the second gate spacer includes an oxygen concentration that decreases from the inner surface towards the outer surface.

3. The semiconductor device structure of claim 2, wherein the first gate spacer and the second gate spacer comprise SiCON.

4. The semiconductor device structure of claim 1, wherein the dielectric spacer comprises SiONC.

5. The semiconductor device structure of claim 1, wherein the first gate spacer has a nitrogen concentration that increases from the inner surface towards the outer surface.

6. The semiconductor device structure of claim 1, further comprising:
an interfacial layer in contact with each semiconductor layer of the plurality of semiconductor layers, wherein the interfacial layer and the dielectric spacer comprise substantially the same material.

7. The semiconductor device structure of claim 1, wherein the dielectric spacer has an oxygen concentration that is less than the oxygen concentration of the first gate spacer.

8. The semiconductor device structure of claim 1, wherein the first gate spacer has an oxygen concentration of about 35 at. % or more at the inner surface.

9. A method for forming a semiconductor device structure, comprising:
forming a sacrificial gate structure and a gate spacer structure over a portion of a fin structure formed over a substrate, the fin structure comprising a plurality of first semiconductor layers and a plurality of second semiconductor layers alternatingly stacked;
removing portions of the fin structure to expose a portion of the substrate;
recessing edge portions of each of the second semiconductor layers to form cavities and forming dielectric spacers in the cavities;
forming source/drain regions on opposite sides of the sacrificial gate structure from the exposed portion of the substrate;
removing the sacrificial gate structure and the second semiconductor layers to expose the gate spacer structure and the dielectric spacers;
subjecting the gate spacer structure and the dielectric spacers to an oxidation process to form an oxidized gate spacer structure and oxidized dielectric spacers, wherein the oxidized gate spacer structure and the oxidized dielectric spacers each have an oxygen concentration that decreases from an inner surface facing a gate region towards an outer surface; and
forming a gate dielectric layer and a gate electrode layer over the oxidized gate spacer structure and surrounding the first semiconductor layers.

10. The method of claim 9, wherein the oxidation process is performed such that the entire gate spacer structure is oxidized to form SiO₂.

11. The method of claim 9, wherein the gate spacer structure comprises a first gate spacer and a second gate spacer, and the oxidation process results in the first gate spacer having a higher oxygen concentration than the second gate spacer.

12. The method of claim 9, further comprising:
forming an interfacial layer on exposed surfaces of each of the first semiconductor layers prior to the oxidation process.

13. The method of claim 12, wherein the oxidation process oxidizes portions of the interfacial layer, and the oxidized interfacial layer, the oxidized gate spacer structure, and the oxidized dielectric spacers comprise substantially the same material.

14. The method of claim 9, wherein the oxidation process comprises exposing the gate spacer structure and the dielectric spacers to oxygen-containing gases at a temperature between about 200 degrees Celsius and about 900 degrees Celsius.

15. The method of claim 9, further comprising:
performing an ion implantation process prior to the oxidation process to implant ion species into the gate spacer structure and the dielectric spacers.

16. A method for forming a semiconductor device structure, comprising:
forming a sacrificial gate structure over a fin structure comprising a first plurality of semiconductor layers and a second plurality of semiconductor layers alternatingly stacked over a substrate;
depositing a gate spacer structure on the sacrificial gate structure, the gate spacer structure comprising a first gate spacer adjacent to the sacrificial gate structure and a second gate spacer over the first gate spacer;
removing portions of the fin structure to expose a portion of the substrate;
recessing the second plurality of semiconductor layers to form cavities and forming dielectric spacers in the cavities;
forming source/drain regions from the exposed portion of the substrate;
removing the sacrificial gate structure and the second plurality of semiconductor layers to expose the first plurality of semiconductor layers, the gate spacer structure, and the dielectric spacers;
forming an interfacial layer on a portion of each of the first plurality of semiconductor layers; and
incorporating fluorine into the first gate spacer, the second gate spacer, and the dielectric spacers to form fluorinated first gate spacer, fluorinated second gate spacer, and fluorinated dielectric spacers, wherein the fluorinated first gate spacer has a higher fluorine concentration than the fluorinated second gate spacer.

17. The method of claim 16, wherein incorporating fluorine comprises a fluorine soak process using a fluorine-containing precursor at a temperature between about 20 degrees Celsius and about 250 degrees Celsius.

18. The method of claim 16, further comprising:
performing a plasma treatment process on the first gate spacer and the dielectric spacers using a hydrogen-containing plasma prior to incorporating fluorine.

19. The method of claim 16, wherein the fluorinated first gate spacer and the fluorinated dielectric spacers have a fluorine concentration of about 2 at. % to about 20 at. %.

20. The method of claim 16, further comprising:
forming a gate dielectric layer over the fluorinated first gate spacer and the fluorinated dielectric spacers immediately after the fluorine incorporation process in a water-free environment to act as a capping layer.
